(19) United States
(12) Patent Application Publication
(10) Pub. No.: US 2012/0097525 A1
(43) Pub. Date: Apr. 26, 2012

(54) METHOD AND APPARATUS TO CONTROL IONIC DEPOSITION

(76) Inventors: Samuel D. HARKNESS, IV, Berkeley, CA (US); Quang N. Tran, San Jose, CA (US)

(21) Appl. No.: 13/093,775

(22) Filed: Apr. 25, 2011

Related U.S. Application Data
(60) Provisional application No. 61/406,697, filed on Oct. 26, 2010.

(51) Int. Cl. C23C 14/34

(52) U.S. Cl. 204/192.12; 204/298.06

(57) ABSTRACT

A sputtering source having a bias field generated between the substrate and the sputtering source. A conductive louver or grid arrangement is positioned in front of the substrate, and is biased by an RF or DC source. The substrate itself may or may not be biased, as needed. The conductive louvers are rotatable to also function as shutters or collimator to control the flux of the deposited species. The shutter arrangement is mounted onto the sputtering opening of a facing target source (FTS). The shutter is biased by an RF or DC source and the applied power and rotation position of each slat in the shutter are controlled to achieve the desired flux and collimation.

### CROSS-REFERENCE TO RELATED APPLICATION

This application claims priority from U.S. Provisional Patent Application No. 61/406,697, filed on Oct. 26, 2010, the entirety of which is incorporated herein by reference.

### BACKGROUND

1. Field

This application relates to the art of forming thin films, such as by physical vapor deposition (PVD). More specifically, this application relates to forming thin film, such as diamond-like coating (DLC) on substrates, such as magnetic disks used in hard drives.

2. Related Art

Hard drive disks are fabricated by forming various thin-film layers over a round substrate. Some of these layers include magnetic materials that is used as the memory medium, and some of these layers are formed as protection. Finally, a lubricant layer is deposited on the surface of the disk to enable smooth flying of the magnetic read/write head. In magnetic disk and similar fabrication processes, the layers are deposited using physical vapor deposition (PVD) by sputtering the deposited material from a target.

Often, it is desired to control the mobility of the arriving sputtered particles on the substrate. Also, in the case of ionic absorbates, it is crucial to use bias to control the energy of the impinging species. At present, the most common manner of controlling ion impact energy at the substrate is to apply bias to the substrate during the sputtering process. For example, an RF or DC power supply is used to apply controllable bias to the substrate, e.g., using a biased cathode. Though this technique has been immensely successful in a wide range of applications, some key issues inhibit its use universally. For example, biasing the substrate may cause excessive heating of the substrate as the flux density of impinging electrons or ions is increased.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to embodiments of the invention, rather than applying bias to the substrate, a bias field is generated between the substrate and the sputtering source. According to one example, a conductive louver or grid arrangement is positioned in front of the substrate, and is biased by an RF or DC source. The substrate itself may or may not be biased, as needed. According to one aspect, the conductive louvers are rotatable to also function as shutters or collimator to control the flux of the deposited species.

According to aspects of the invention, a shutter arrangement is mounted onto the sputtering opening of a facing target source (FTS). The shutter is biased by an RF or DC source and the applied power and rotation position of each slat in the shutter are controlled to achieve the desired flux and collimation.

According to other aspects of the invention, a thin film is formed on a substrate by operating a sputtering source to generate ion species for deposition on the substrate. A retarding field is generated in front of the substrate so as to reduce the energy of the ion species prior to implantation onto the substrate. According to one embodiment, the retarding field is generated by applying a bias to a conductive arrangement placed in front of the substrate and facing the sputtering source.

According to yet other aspects of the invention, a method for performing physical vapor deposition on a substrate is provided, comprising: energizing a sputtering source to ignite and sustain plasma therein, such that ions are emitted from an aperture of the sputtering source; transporting the substrate in front of the aperture while ions are emitted from the aperture; and applying a bias field between the substrate and the aperture. The bias field can be generated by applying a voltage of between +100 V and −300 volts to a bias field applicator positioned between the substrate and the sputtering source. The method may further comprise changing the trajectory direction of the ions after the ions exit the aperture, to thereby control the adsorbate angle of incidence of the ions on the substrate.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 illustrates a system according to an embodiment of the invention;

FIG. 2 illustrates a cross section of one of chambers 140;

FIG. 3 is a simplified schematic illustrating a combination source according to an embodiment of the invention, viewed from inside of the chamber, as shown in broken-line arrows A-A in FIG. 2.

FIG. 4A illustrates the shutter according to an embodiment of the invention, while FIG. 4B is an isometric view of the shutter of FIG. 4A.

FIG. 5 is a plot of densities versus shutter bias voltage for carbon films grown according to embodiment of the invention.

### DETAILED DESCRIPTION

A detailed description will now be given of a processing system according to embodiments of the invention. Embodiments of the invention may be implemented in various sputtering systems, however, for clarity of description, the embodiments described herein relate to fabrication of disks used in hard disk drives. However, it should be appreciated that the invention is not limited only to such systems.

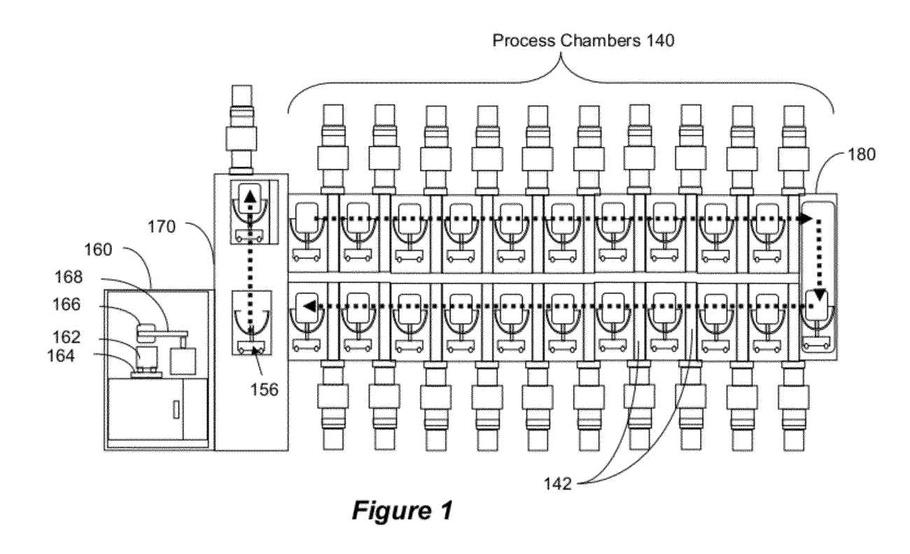

FIG. 1 illustrates a system for high capacity sequential processing of substrates, which employs unique sputter deposition sources. The system is especially beneficial for fabrication of disks for hard disk drives, but can also be used for fabrication of other devices, such as solar cells, light emitting diodes, etc. In one embodiment, the invention is implemented on an Intevac 200 Lean™ disc-sputtering machine, available from Intevac of Santa Clara, Calif. The system is generally constructed of several identical processing chambers 140 connected in a linear fashion, such that substrates can be transferred directly from one chamber to the next. While in the embodiment of FIG. 1 two rows of chambers are stacked one on top of the other, this is not necessary, but it provides a reduced footprint.

A front end module 160 includes tracks 164 for transporting cassettes 162 containing a given number of substrates 166. The front end unit 160 maintains therein a clean atmospheric environment. A robotic arm 168 or other system (e.g., knife edge lifter) removes substrates 166, from the cassette 162 and transfers them into a loading module 170. Loading module 170 loads each substrate 166 onto a substrate carrier 156, and moves the substrate 166 and carrier 156 into a vacuum environment. According to another implementation, the loading module is already in vacuum environment, so that the loading of the substrate onto the carrier is done in vacuum environment.

In the embodiment of FIG. 1, each carrier is shown to hold a single substrate, but other embodiments can utilize carriers that hold two substrates, either in tandem or back to back. Thereafter the carriers 156 and substrates 166 traverse the processing chambers 140, each of which operates in vacuum and is isolated from other processing chambers by gate valves 142 during processing. The motion of the carrier 156 is shown by the broken-line arrows. Once processing is completed, the substrate 166 is removed from the carrier 156 and is moved to an atmospheric environment and placed in the cassette 162 by robot arm 168.

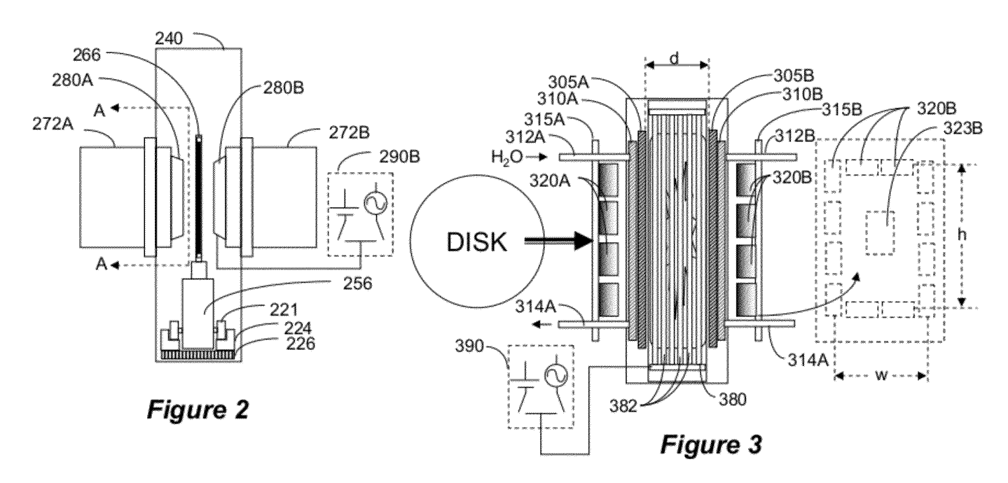

In FIG. 1, each of chambers 140 can be tailored to perform a specific process. For example, some chambers may be fitted with a heater to heat or anneal the substrate; some chambers may be fitted with standard sputtering source to deposit magnetic material on the surface of the substrate, etc. FIG. 2 illustrates a cross section of one of chambers 140 which is fitted with two sputtering sources 272A and 272B, according to an embodiment of the invention. Substrate 266 is shown mounted vertically onto carrier 256. Carrier 256 has wheels 221, which ride on tracks 224, but the reverse can also be implemented, i.e., the carrier may have tracks which ride on wheels situated in the chamber. The wheels 221 may be magnetic, in which case the tracks 224 may be made of paramagnetic material. In this embodiment the carrier is moved by linear motor 226, although other motive forces and/or arrangements may be used. Depositions source 272A is shown mounted onto one side of the chamber 240, while deposition source 272B is mounted on the other, opposite, side of the chamber. The carrier passes by deposition source 272, such that deposition is performed on the surface of the substrate as the substrate is moved passed the source.

As shown in FIG. 2, sputter sources 272A and 272B generate ions for deposition onto the substrate 266. The ions are generated by sustaining plasma of, e.g., argon gas, within the sputtering source, such that the argon ions in the plasma sputter targets made of the material to be deposited onto the substrate 266. When atoms of the material to be deposited are ejected from the target they are ionized by electrons accelerated within the plasma region. The ions are then directed towards the substrate. According to embodiments of the invention, the energy of the ions may be increased or reduced prior to impinging on the substrate by a field generated just ahead of the substrate. In the embodiment illustrated in FIG. 2, the field is generated by biasing shutters 280A and 280B, which are biased by an RF or DC power source, as exemplified by power source 290B.

FIG. 3 is a schematic illustration of one of sources 272A, 272B, as they appear looking head on from inside the chamber, as shown by arrows A-A in FIG. 2. In this arrangement, sputtering targets 305A, 305B, which in this example are comprised of conductive graphite, stand facially opposed each other at a separation distance “d” governed by the resultant magnetic field found in the mid-gap between the two. In this example, the targets abut heat sinks in the form of cooling plates 310A, 310B, in which cooling fluid, such as water, circulate.

Behind each target, a mounting plate, e.g., stainless steel plate 315A, 315B, is provided with magnets 320A, 320B. The magnets are arranged about the periphery of the mounting plate 315A, 315B, so that one of the magnetic pole is pointed towards the target. This can be seen more clearly from the phantom drawings shown in broken-line in FIG. 3. In FIG. 3, each magnet is shown shaded such that the darker side signifies a north magnetic pole and the lighter side signifies a south magnetic pole. In the example of FIG. 3, the magnets are arrange such that their magnetic pole is facing the target and is of opposite polarity of the corresponding magnet on the other target. That is, as can be seen in FIG. 3, magnets 320A have their lighter side, i.e., their south magnetic pole pointed towards target 305A, while the corresponding magnets 320B have their darker side, i.e., their north pole pointing towards target 305B.

According to aspects of the invention, the separation “d” of the targets and the magnets are selected according to a defined relationship so as to enable the formation of the desired film having the desired properties, especially density property. In this example the separation distance “d” between the target pair is designed to be between 30 and 300 mm and preferably between 40 and 200 mm. The maximum magnet energy products for the individual magnets 320A, 320B, ranges between 200 kJ/m³<BHₘₐₓ<425 kJ/m³ and preferably 300 kJ/m³<BHₘₐₓ<400 kJ/m³. This combination of ranges has shown to enable the deposition of high quality DLC film.

In FIG. 3, the bias field at the opening of the sputtering source (i.e., in front of the substrate) is generated by applying an electrical potential to shutter 380. In this example, shutter 380 is made of rotatable slats 382. The slats are rotatable, so that they can be used as collimator as well as to control the ion flux from the sputtering source to the substrate. Bias source 390 applied bias power to the slats, which may be AC or DC power, although in the described embodiments it is a DC bias.

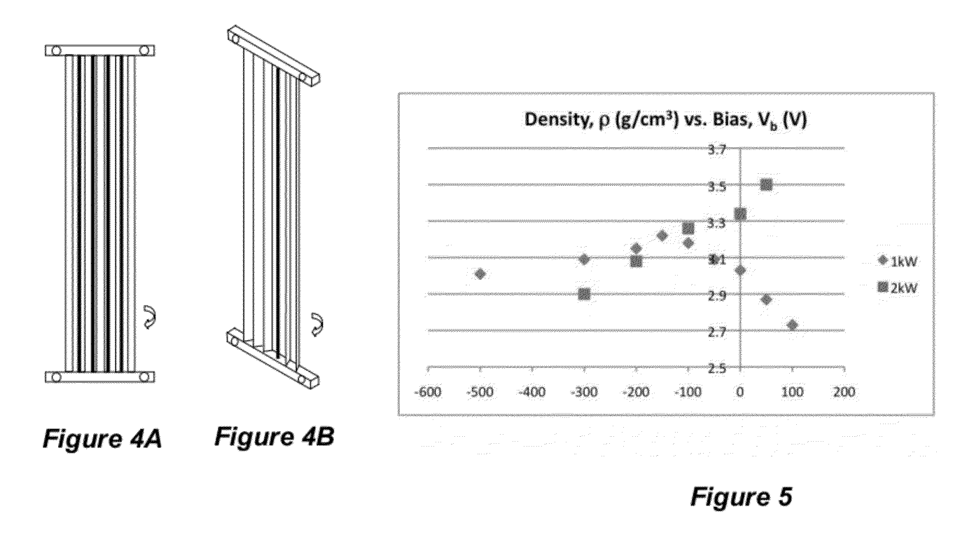

FIG. 4A illustrates the shutter according to an embodiment of the invention, while FIG. 4B is an isometric view of the shutter of FIG. 4A. As shown in FIGS. 4A and 4B, the slats of the shutter can be rotated, and in FIGS. 4A and 4B they are positioned so as to “fan” the ions passing therethrough. When all of the slats are positioned parallel to each other, they form a collimator. Also, in some embodiments the slats can be positioned so as to totally block ions from reaching the substrate.

In embodiments where a positive bias is called for, i.e., those where ion energy is retarded and electrons are accelerated, the array of vertical slats 382 are arranged parallel to each other as shown in FIGS. 2-4. The entire unit is attached to the vacuum chamber wall with insulating hardware, so that the bias applied to the shutter is not conducted to the chamber's body or other elements of the chamber. When used in conjunction with a facing target cathode pair, such as that illustrated in FIGS. 2 and 3, the slats unit covers the aperture connecting the cathode cavity and the transport chamber. Electrical connection can be made via a vacuum feedthrough or other methods. The slats can be adjusted to allow the process engineer the ability to tailor the solid angle of the desired adsorbate incidence on the substrate.

In certain embodiments, the slats are separated by at least 1 cm from each other. The slats may be bead-blasted or arc sprayed to roughen the surface, which allows adhesion of thick deposits of adsorbed sputter material and avoids flaking.

Because the slats will shadow portions of the substrate, the substrate (e.g., a disc) is scanned by the unit throughout the deposition cycle, as shown by the double-line arrow in FIG. 3. Alternatively, the substrate can be rotated during deposition so that the whole surface receives the same total flux.

### Example I

An embodiment process for depositing a DLC on a substrate to produce a viable magnetic recording disc will now be described. It is assumed that the process preceding the carbon overcoat step is generalized to include a series of front end cleaning operations and possible mechanical texturing in preparation for multilayer deposition. Furthermore, it is also assumed that the preceding steps occurring prior to carbon deposition include some combination of magnetic and non-magnetic materials (predominantly metals) and that the disc temperature heading into the carbon deposition station is in the range of 300-500 K. A process for ta-C carbon deposition then ensues with the cathode pairs, such that each has a target pair separated by 50 mm with a N-S-N magnet array on one side, and a S-N-S array on the opposing side. The arrays are powered by 354 kJ/m³ NdFeB permanent magnets. The substrate is initially located aft of the chamber centerline (of which the cathode pair(s) gap is co-located). Prior to turning on the flow of argon, the chamber background pressure is less than about 2×10⁻⁴ Pa. When the Ar-pressure is stabilized at 0.1 Pa, the cathodes are powered on by applying between 250 and 3500 watts, and the bias voltage is applied to the slat unit (e.g., between +100 V and −300 volts). The substrate then begins to travel past the cathode aperture to the fore of center position. The speed of travel is determined by the desired throughput of the overall system. When the substrate reaches the fore position, the power is turned off and the gas mass-flow-controllers (MFC) are closed allowing the chamber to regenerate the base conditions for the next disc to be processed. The disc is then either exited from the system, or subjected to a further processing step to further condition the film surface. After removal from vacuum, the disc is then put through backend processing where it receives a thin lubricant layer, post-deposition polishing and flyability assurance testing.

Shown in FIG. 5 is a plot of densities versus shutter bias voltage for carbon films grown in the abovementioned manner directly on a NiP/Al disc substrate. The diamond-shape data points are for cathode power of 1000 watt, while the square-shaped data point are for plasma maintained at 2000 watt cathode power. As can be seen, when the bias voltage applied generates a retarding field, i.e., positive voltage, it reduces the energy of the carbon ions, such that using the 1000W power, the density of the film is reduced. On the other hand, when using the 2000W power, the amount on ionized carbon atoms relative to neutrals is high, and the film's density is increased. Using proper ionization and retarding field, densities as high as 3.5 g/cm³ can be achieved.

### Example II

In the following example, the biased shutter arrangement is applied to a facing target sputtering (FTS) source, especially designed to enable high arrival rates of ionized atoms to a substrate situated remotely from the plasma. In the application for depositing ta-C films, highly ionized carbon atoms are required. Specifically, a minimum of 30 eV adatom energy is believed to be required for sp³ formation. Therefore, the following embodiments of the invention are structured to deliver 30-100 eV adatom energy, wherein the optimal energy is 54 eV. These embodiments of the invention enable the fabrication of DLC densities greater than 2.7 g/cm³ and without the incorporation of process hydrogen.

As shown in FIG. 3, according to embodiments of the invention, the magnets are arranged so as to define an axis height, h, and width, w, of the magnet array. The axis height and width are set such that the flattening factor is above 0.65. That is: flattening factor f=(h−w)/h, >0.65.

In this example, a plurality of 354 kJ/m³ magnets are placed upon a 410 stainless steel mounting plate, which is subsequently attached directly behind each target's heatsink. The outer ring of magnets all have the same polarity, and the opposite polarity to the magnet plate constructed for the opposing target. An optional field-bending magnet 323B is added at the center of the mounting plate, so as to bend the magnetic field generated by the outer ring of magnets 320B. This provides an improved confinement of the plasma. In this example, an equal or weaker magnet 323B (BHₘₐₓ≦354 kJ/m³) of opposite polarity of magnets 320B interposed within the outer ring.

### Example III

A process to produce a viable magnetic recording disc has been developed, using the described magnetron. The process preceding the carbon overcoat step is generalized to include a series of front end cleaning operations and possible mechanical texturing in preparation for multilayer deposition, which is not particularly relevant to the method of the invention. Furthermore, it is assumed that the preceding steps occurring prior to carbon deposition include some combination of magnetic and non-magnetic materials (predominantly metals) and that the disc temperature heading into the carbon deposition station is in the range of 300-500 K. A ta-C carbon (tetrahedral amorphous carbon) deposition then ensues with the cathode pairs (one about each side of the disc) such that each has a target pair separated by 50 mm, with peripheral magnets having north magnetic pole pointing towards the target and a center magnet having a south magnetic pole pointing towards the target. The target on the opposite side had the opposite magnetic arrangement, i.e., peripheral magnets having south magnetic pole pointing towards the target and a center magnet having a north magnetic pole pointing towards the target having. The arrays are powered by 354 kJ/m³ NdFeB permanent magnets.

The substrate is initially located aft of the chamber centerline (of which the cathode pair(s) gap is co-located), such that it is not exposed to the sputtering. Prior to turning on the flow of argon, the chamber background pressure is <2×10⁻⁴ Pa. When the Ar-pressure is then stabilized at 0.1 Pa, the cathodes are powered (generally between 250 and 3500 W, but here power of 1000 W to 2000W is used) on and the substrate begins to travel past the cathode aperture to the fore of center position (as shown by the double-arrow in FIG. 3). The speed of travel is determined by the desired throughput of the overall system. This “scan” approach allows enhanced thickness uniformity for the final carbon film. A bias voltage is applied to the slat unit, which in this example is a retarding positive bias, so as to reduce the energy of the carbon ions prior to reaching the substrate. When the substrate reaches the fore position, the power is turned off and the gas mass-flow-controllers (MFC) are closed allowing the chamber to regenerate the base condition for the next disc to be processed. The disc is then either exited from the system, or subjected to a further processing step to further condition the film surface.

The resulting process carried out in the described apparatus provides high density carbon film (DLC) in the range of 2.4-3.5 g/cm³. In the described embodiments, the target and plasma are remote from the disk, so a highly ionized carbon atoms can be generated to result in high density carbon film. The magnetic field is lowered, thereby resulting in higher ionization cross-section. That is, the apparatus described herein uses remote plasma with low magnetic field to generate highly ionized carbon atoms. The facing targets as described confine the plasma. Low argon pressure can be used.

The present invention has been described in relation to particular examples, which are intended in all respects to be illustrative rather than restrictive. Those skilled in the art will appreciate that many different combinations of hardware, software, and firmware will be suitable for practicing the present invention. Moreover, other implementations of the invention will be apparent to those skilled in the art from consideration of the specification and practice of the invention disclosed herein. Various aspects and/or components of the described embodiments may be used singly or in any combination in the server arts. It is intended that the specification and examples be considered as exemplary only, with a true scope and spirit of the invention being indicated by the following claims.

1. A sputtering source, comprising:
a vacuum chamber having an ion emitting aperture;
a sputtering target provided within the chamber;
a plasma power applicator for igniting and sustaining plasma within the chamber;
a bias field apparatus provided across from the aperture;
a bias power source coupled to the bias field apparatus.

2. The sputtering source of claim 1, further comprising a second sputtering target provided inside the vacuum chamber in a facing relationship to the sputtering target.

3. The sputtering source of claim 1, wherein said bias source comprises a DC power source.

4. The sputtering source of claim 3, wherein said bias field apparatus comprises a louver arrangement having rotatable slats.

5. The sputtering source of claim 4, wherein the sputtering source applies voltage of between +100 V and −300 volts to the slats.

6. The sputtering source of claim 4, wherein the slats are separated by 5 mm to 30 mm.

7. The sputtering source of claim 5, wherein the plasma power applicator comprises cathode coupled to plasma power source.

8. The sputtering source of claim 7, further comprising an array of magnets provided behind the sputtering target.

9. The sputtering source of claim 2, further comprising a first array of magnets provided behind the sputtering target and a second array of magnets provided behind the second sputtering target, and wherein the polarity of the first array of magnets is oriented opposite the polarity of the second array of magnets.

10. A deposition system for depositing a layer onto a substrate, comprising:
a processing chamber;
a sputtering source provided on one side of the processing chamber;
a transport mechanism provided within the processing chamber to scan the substrate while the sputtering source is energized;
wherein the sputtering source comprises:
a vacuum chamber having an ion emitting aperture;
a sputtering target provided within the vacuum chamber;
a plasma power applicator for igniting and sustaining plasma within the chamber;
a bias field apparatus provided across from the aperture;
a bias power source coupled to the bias field apparatus.

11. The system of claim 10, further comprising a second sputtering source provided on the processing chamber in a facing relationship to the sputtering source, and a second bias field apparatus, to thereby facilitate dual-sided deposition simultaneously on the substrate.

12. The system of claim 11, wherein the bias power source applies a voltage of between +100 V and −300 volts to each of the bias field apparatus and the second bias field apparatus.

13. The system of claim 10, wherein each of the bias field apparatus and the second bias field apparatus comprise a shutter arrangement.

14. The system of claim 13, wherein the shutter arrangement comprises a plurality of parallel rotatable slats.

15. A method for performing physical vapor deposition on a substrate, comprising:
energizing a sputtering source to ignite and sustain plasma therein, such that ions are emitted from an aperture of the sputtering source;
transporting the substrate in front of the aperture while ions are emitted from the aperture;
applying a bias field between the substrate and the aperture.

16. The method of claim 15, wherein the step of applying a bias field comprises applying a retarding field to reduce the energy of the ions prior to the ions reaching the substrate.

17. The method of claim 15, wherein the step of applying a bias field comprises applying a voltage of between +100 V and −300 volts to a bias field applicator positioned between the substrate and the sputtering source.

18. The method of claim 16, further comprising changing the trajectory direction of the ions after the ions exit the aperture, to thereby control the adsorbate angle of incidence of the ions on the substrate.

19. The method of claim 16, further comprising collimating the ions after the ions exit the aperture to thereby generate an oblique flux of ions.

20. The method of claim 15, further comprising applying a magnetic field of 200 kJ/m³<BHₘₐₓ<425 kJ/m³ to the sputtering source.
